(19) United States
(12) Patent Application Publication
(10) Pub. No.: US 2025/0070001 A1
(43) Pub. Date: Feb. 27, 2025

(54) DEVICE INCLUDING SUBSTRATE WITH PASSIVE ELECTRONIC COMPONENT EMBEDDED THEREIN

(71) Applicant: QUALCOMM Incorporated, San Diego, CA (US)

(72) Inventors: Aniket PATIL, San Diego, CA (US); Joan Rey Villarba BUOT, Escondido, CA (US); Hi MOON, Suwon-si (KR)

(21) Appl. No.: 18/455,439

(22) Filed: Aug. 24, 2023

(51) Int. Cl. H01L 23/498; H01L 23/00; H01L 23/538; H01L 25/065

(52) U.S. Cl. CPC H01L 23/49816; H01L 23/49822; H01L 23/5389; H01L 24/08; H01L 24/32; H01L 25/0652; H01L 2224/08113; H01L 2224/08146; H01L 2224/32146; H01L 2224/32235; H01L 2924/1205; H01L 2924/15311

(57) ABSTRACT

A device includes a core including an upper core dielectric layer, a lower core dielectric layer, a central core dielectric layer contacting the upper core dielectric layer and the lower core dielectric layer, and a passive electronic component embedded within the central core dielectric layer. The device includes an upper laminate stack coupled to the upper core dielectric layer. The upper laminate stack includes upper metal layers and contact pads configured to electrically connect a die to the passive electronic component by way of conductive paths defined by the set of upper metal layers. The device includes a lower laminate stack coupled to a bottom surface of the lower core dielectric layer. The lower laminate stack includes lower metal layers and a set of lower dielectric layers disposed between adjacent metal layers of the set of lower metal layers.

### FIELD Various features relate to integrated devices.

### BACKGROUND

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

State-of-the-art mobile application devices demand a small form factor, low cost, a tight power budget, and high electrical performance. Mobile package design has evolved to meet these divergent goals for enabling mobile applications that support multimedia enhancements. These mobile applications, however, are susceptible to power and signal routing issues when multiple dies are arranged within the small form factor. Design and manufacture of devices for use in mobile applications is challenging due to conflicts among the various design goals. For example, smaller form factor devices are generally more expensive to design and manufacture and small size can exacerbate other issues, such as heat management.

As another example, power distribution network (PDN) performance of a device can be improved by electrically connecting the PDN to appropriate passive components (e.g., capacitors); however, adding such passive components tends to increase package size or limit area available for other components. In some cases, passive components can be embedded within a package substrate to mitigate size and area concerns (as well as to address other issues); however, embedding passive components within the package substrate introduces further challenges, which may limit routing options and/or require use of more layers in the package substrate.

### SUMMARY

Various features relate to integrated devices.

One example provides a device that includes a core including an upper core dielectric layer, a lower core dielectric layer, a central core dielectric layer in direct contact with a bottom surface of the upper core dielectric layer and in direct contact with a top surface of the lower core dielectric layer, and a passive electronic component embedded within the central core dielectric layer. The device also includes an upper laminate stack coupled to a top surface of the upper core dielectric layer. The upper laminate stack includes a set of upper metal layers and a set of contact pads configured to electrically connect a die to the passive electronic component by way of conductive paths defined by the set of upper metal layers. The device also includes a lower laminate stack coupled to a bottom surface of the lower core dielectric layer. The lower laminate stack includes a set of lower metal layers including a first lower metal layer directly in contact with the bottom surface of the lower core dielectric layer. The lower laminate stack also includes a set of lower dielectric layers disposed between adjacent metal layers of the set of lower metal layers.

Another example provides a device that includes a core including a passive electronic component embedded therein. The device also includes an upper laminate stack coupled to the core. The upper laminate stack includes a set of contact pads configured to electrically connect a die to the passive electronic component by way of conductive paths defined by one or more upper metal layers of the upper laminate stack. The device also includes a lower laminate stack coupled to the core. The lower laminate stack includes a set of lower metal layers. A metal layer closest to the core among the set of lower metal layers includes one or more traces that pass through a shadow of the passive electronic component.

Another example provides a method of fabrication of a device. The method includes providing a core. The core includes a central core dielectric layer in which a passive electronic component is embedded, an upper core dielectric layer on a top surface of the central core dielectric layer, and a lower core dielectric layer on a bottom surface of the central core dielectric layer. The method includes forming an upper laminate stack on a top surface of the upper core dielectric layer. The upper laminate stack includes a set of upper metal layers and a set of contact pads configured to electrically connect a die to the passive electronic component by way of conductive paths defined by the set of upper metal layers. The method includes forming a lower laminate stack on a bottom surface of the lower core dielectric layer. The lower laminate stack includes a set of lower metal layers including a first lower metal layer directly in contact with the bottom surface of the lower core dielectric layer.

Another example provides a method of fabrication of a device. The method includes providing a core including a passive electronic component embedded therein. The method also includes forming an upper laminate stack coupled to the core. The upper laminate stack includes a set of contact pads configured to electrically connect a die to the passive electronic component by way of conductive paths defined by one or more upper metal layers of the upper laminate stack. The method also includes forming a lower laminate stack coupled to the core. The lower laminate stack includes a set of lower metal layers. A metal layer closest to the core among the set of lower metal layers includes one or more traces that pass through a shadow of the passive electronic component.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a schematic cross-sectional profile view of an example of a device that includes a substrate including a passive electronic component embedded therein.

FIG. 2 illustrates a schematic cross-sectional profile view of another example of a device that includes a substrate including a passive electronic component embedded therein.

FIG. 3 illustrates a schematic cross-sectional profile view of another example of a device that includes a substrate including a passive electronic component embedded therein.

FIGS. 4A and 4B together illustrate an exemplary sequence for fabricating a device that includes a substrate including a passive electronic component embedded therein.

FIG. 5 is a flowchart illustrating an exemplary method for fabricating a device that includes a substrate including a passive electronic component embedded therein.

FIG. 6 is a flowchart illustrating another exemplary method for fabricating a device that includes a substrate including a passive electronic component embedded therein.

FIG. 7 illustrates various electronic devices that may integrate a die, an electronic circuit, an integrated device, a substrate, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure. As another example, various devices and structures disclosed herein are illustrated schematically. Such schematic representations are not to scale and are generally intentionally simplified. To illustrate, integrated devices can have many tens or hundreds of contacts and corresponding interconnections; however, a very small number of such contacts and interconnects are illustrated herein to highlight important features of the disclosure without unduly complicating the drawings.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

In some drawings, multiple instances of a particular type of feature are shown. In some circumstances, fewer than all of such features may be identified using a reference number. For example, a single reference number may be shown and associated with a representative instance of the feature so as not to obscure other aspects of the drawings.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

Improvements in manufacturing technology and demand for lower cost and more capable electronic devices has led to increasing complexity of integrated circuits (ICs). Often, more complex ICs have more complex interconnection schemes to enable interaction between ICs of a device. The number of interconnect levels for circuitry has substantially increased due to the large number of devices that are now interconnected in a state-of-the-art mobile application device.

These interconnections include back-end-of-line (BEOL) interconnect layers, which may refer to the conductive interconnect layers for electrically coupling to front-end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middle-of-line (MOL) interconnect layers, which interconnect to the FEOL active devices of an IC.

State-of-the-art mobile application devices demand a small form factor, low cost, a tight power budget, and high electrical performance. Mobile package design has evolved to meet these divergent goals for enabling mobile applications that support multimedia enhancements. One approach to reducing package size is to integrate multiple dies within a single package. One example of a multi-die package is a two-dimensional (2D) package architecture, in which two or more dies are coupled to a package substrate side-by-side with one another. Dies in this configuration can interact with one another (e.g., via die-to-die connections) and with off-package devices (e.g., via off-package connections). A challenge of such configurations is that die-to-die and off-package connections have different design criteria. For example, off-package connections are generally larger (e.g., in terms of line width, line spacing, etc.) than is needed for die-to-die connections. Various workarounds have been used to address this size difference. For example, additional devices (e.g., interposer devices or bridge die) can be added to a package to route die-to-die connections using smaller lines. As another example, additional layers or a separate stacked substrate can be added to the package substrate to provide die-to-die connection and redistribution routing to connect to off-package connections.

Another approach to reducing package size is a 2.5D architecture, in which two or more devices are positioned side-by-side with one another on the package substrate, and one or more additional devices are stacked on at least one of the side-by-side devices. To illustrate, a stacked die arrangement can be coupled to a package substrate side-by-side with another die, a passive device, another die stack, etc. Stacked die schemes and chiplet architectures are becoming more common as significant power performance area (PPA) yield enhancements are demonstrated for stacked die and chiplet architecture product lines.

Passive devices, such as integrated capacitor devices, can be embedded within a core of a package substrate to improve power distribution network performance. However, embedding a passive device in the core of the substrate can introduce other challenges. For example, a typical core used in an integrated device package includes a dielectric layer with a metal layer (e.g., a copper foil) on each side. A portion of the dielectric layer and portions of each of the metal layers are removed to form an opening in which the passive device is embedded. Before or after embedding the passive device in the core, the metal layers are patterned to form traces and pads of the substrate. As a result of these operations, the closest metal layer over the core does not include metal directly above the embedded passive device and the closest metal layer below the core does not include metal directly beneath the embedded passive device. Absence of metal in these locations means that traces cannot be routed directly above or directly below the embedded passive device in these layers, which limits routing options and may in some cases require the use of more metal layers in the substrate to meet routing requirements, which increases the overall thickness of the substrate and an integrated device associated with the substrate.

Additionally, absence of metal in these locations means that a conductive path between the embedded passive device and a power distribution network of a die coupled to the package cannot be routed through the closest metal layer to the core. As a result, the conductive path between the embedded passive device and the power distribution network is routed through other metal layers, which can entail the use of longer conductive paths. Longer conductive paths are associated with increased inductance and resistance, each of which reduces PDN performance.

Aspects disclosed herein address each of the challenges above by adding relatively thin dielectric build-up layers to the core. In particular, a passive electronic component can be embedded within a central core layer, and top and bottom build-up layers can be disposed over the central core layer and the passive electronic component embedded therein. The closest metal layer above the core is coupled to the top build-up layer, and the closest metal layer beneath the core is coupled to the bottom build-up layer. As a result of this arrangement, the first metal layer above the core can be patterned to include conductors (e.g., traces and/or pads) directly above the embedded passive electronic component. Likewise, the first metal layer beneath the core can be patterned to include conductors (e.g., traces and/or pads) directly beneath the embedded passive electronic component. A technical benefit of this arrangement is increased routing flexibility. An additional technical benefit of this arrangement is that the conductive path from the embedded passive electronic component to a PDN can be shortened, thereby reducing the inductance and resistance of the conductive path, and improving PDN performance.

The trace routing limitations described above could be addressed by the addition of more layers to the substrate. For example, if routing requirements cannot be achieved due to the inability to route traces or to position pads directly above or below the passive electronic component in the first metal layer from the core, adding more metal layers (and dielectric layers therebetween) can provide additional routing options. However, the implementations disclosed herein solve these challenges without adding more layers, and as a result, can provide more compact substrates. Further, in contrast to the disclosed implementations, adding more layers does not resolve, and may exacerbate, challenges associated with interconnecting the embedded passive electronic component to the PDN.

### Exemplary Device Including Substrate With Passive Electronic Component Embedded Therein

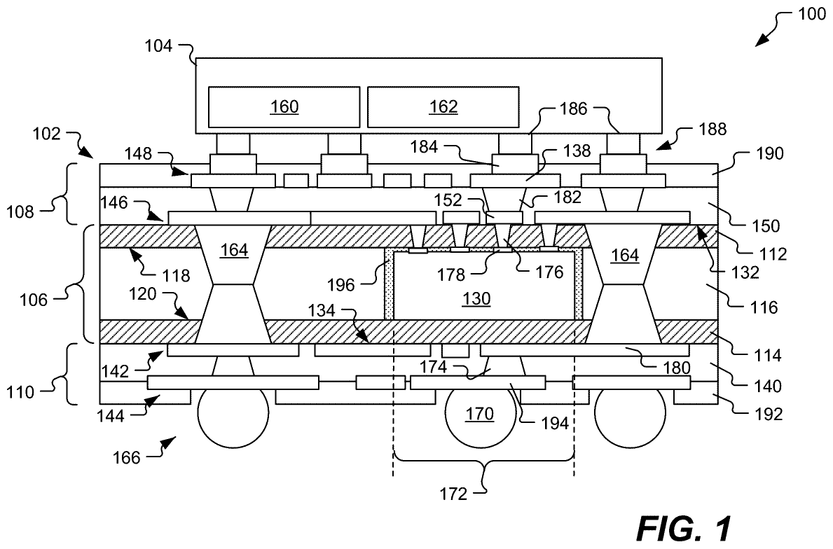

FIG. 1 illustrates a schematic cross-sectional profile view of an example of a device 100 that includes a substrate 102 including a passive electronic component 130 embedded therein. One or more dies (e.g., a die 104) are electrically connected to conductors of the substrate 102. In particular, the die 104 is electrically connected to the passive electronic component 130 and to off-package contacts 166 (e.g., contacts of a ball grid array (BGA)) via the conductors of the substrate 102. As described in more detail below, the passive electronic component 130 is embedded within a core 106 of the substrate 102, and one or both of the closest metal layers (e.g., a metal layer 146, a metal layer 142, or both) to the core 106 include conductors (e.g., traces and/or pads) within or passing through a region corresponding to a shadow 172 of the passive electronic component 130.

The die 104 includes circuitry, such as a plurality of transistors 160 and/or other circuit elements arranged and interconnected to form a power distribution network (PDN) 162. The transistors 160 can be arranged to form logic cells, memory cells, amplifiers, other active circuit elements, or combinations thereof. Components of the circuitry can be formed in and/or over a semiconductor substrate of the die 104. Different implementations can use different types of transistors 160, such as a field effect transistor (FET), planar FET, finFET, a gate all around FET, or mixtures of transistor types. In some implementations, a front end of line (FEOL) process may be used to fabricate the circuitry in and/or over the semiconductor substrate to form the die 104.

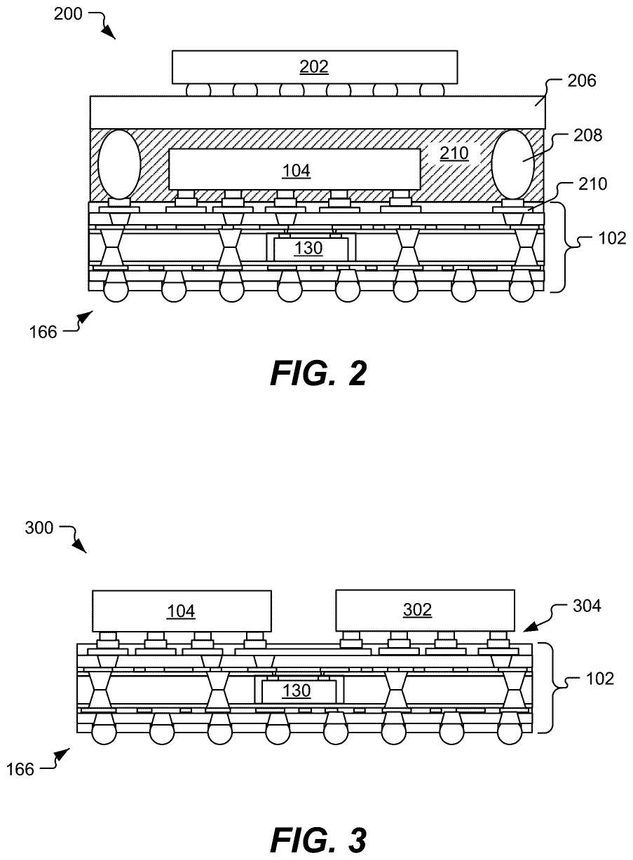

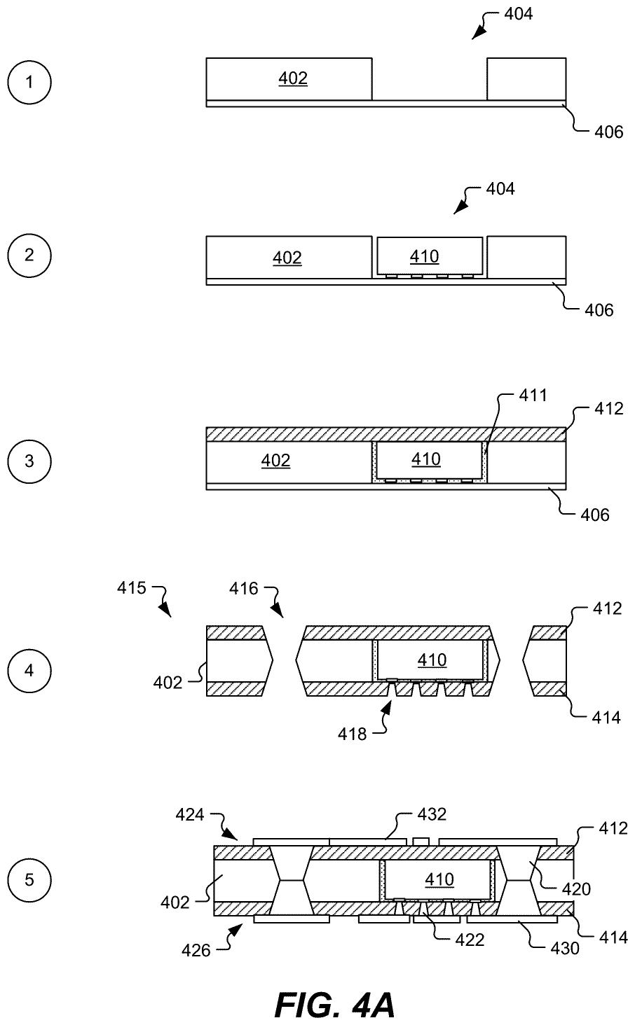

The circuitry of the die 104 is electrically connected to a set of contacts 186 of the die 104. The contacts 186 are configured to be electrically connected, via conductors of the substrate 102, to one or more other dies (e.g., as described with reference to FIG. 2 or FIG. 3), to off-package devices by way of the off-package contacts 166, to the passive electronic component 130, or combinations thereof. As one example, the passive electronic component 130 can include an integrated capacitor device (such as a deep trench capacitor device or a multilayer ceramic capacitor device) that is coupled to the PDN 162 of the die 104 to improve performance of the PDN 162.

The substrate 102 includes the core 106, an upper laminate stack 108, and a lower laminate stack 110. The core 106 includes an upper core dielectric layer 112, a lower core dielectric layer 114, and a central core dielectric layer 116 in direct contact with a bottom surface 118 of the upper core dielectric layer 112 and in direct contact with a top surface 120 of the lower core dielectric layer 114. The upper core dielectric layer 112 and the lower core dielectric layer 114 are thinner than the central core dielectric layer 116. As one example, the central core dielectric layer 116 has a thickness in the range of 40 to 210 micrometers, and each of the upper core dielectric layer 112 and the lower core dielectric layer 114 has a thickness less than 20 micrometers, such as 8 to 12 micrometers. In a particular implementation, the upper core dielectric layer 112 and the lower core dielectric layer 114 are formed in place on the central core dielectric layer 116 to form the core 106. For example, each of the upper core dielectric layer 112 and the lower core dielectric layer 114 can include or correspond to a resin layer or a resin embedded layer (e.g., a prepreg layer) applied to the central core dielectric layer 116 and cured to form a layer of the core 106. In this example, the upper core dielectric layer 112 and the lower core dielectric layer 114 can be referred to as build-up layers.

The passive electronic component 130 is embedded within the central core dielectric layer 116. For example, the central core dielectric layer 116 can include an opening in which the passive electronic component 130 is disposed. A resin 196 can be disposed in the opening in the central core dielectric layer 116 to retain the passive electronic component 130. The upper core dielectric layer 112 covers a top surface of the central core dielectric layer 116, which includes covering the opening in which the passive electronic component 130 is disposed. The lower core dielectric layer 114 covers a bottom surface of the central core dielectric layer 116, which includes covering the opening in which the passive electronic component 130 is disposed. Contacts 178 of the passive electronic component 130 are electrically connected to the conductors of the metal layer 146 by conductive vias 176 that extend through the upper core dielectric layer 112.

The upper laminate stack 108 is coupled to a top surface 132 of the upper core dielectric layer 112. The upper laminate stack 108 includes a set of upper metal layers (e.g., the metal layer 146 and a metal layer 148) separated by upper dielectric layer(s) (e.g., dielectric layer 150). In the example illustrated in FIG. 1, the metal layer 146 is directly in contact with the top surface 132 of the upper core dielectric layer 112. The upper laminate stack 108 also includes interconnections (e.g., conductive vias 182) between the metal layers and through the dielectric layer(s). Although FIG. 1 illustrates the upper laminate stack 108 as including two metal layers and one dielectric layer therebetween, in some implementations, the set of upper metal layers can include more than two metal layers, and dielectric layers therebetween.

The upper laminate stack 108 also includes a set of contact pads (e.g., a contact pad 138 in the metal layer 148) configured to electrically connect the die 104 to the passive electronic component 130 by way of conductive paths defined by the set of upper metal layers. For example, in FIG. 1, the contact pad 138 is electrically connected to a contact 186 of the die 104 via a bump pad 184 that extends through a solder resist layer 190 of the upper laminate stack 108 and by a solder bump of a set of microbumps 188 of the die 104. The contact pad 138 is also connected to a pad or trace (e.g., a trace 152) of the metal layer 146 by a conductive via 182. The pad or trace of the metal layer 146 is electrically connected to one of the contacts 178 of the passive electronic component 130 by way of one of the conductive vias 176 through the upper core dielectric layer 112.

The lower laminate stack 110 is coupled to a bottom surface 134 of the lower core dielectric layer 114. The lower laminate stack 110 includes a set of lower metal layers (e.g., the metal layer 142 and a metal layer 144) separated by dielectric layers (e.g., a dielectric layer 140). In the example illustrated in FIG. 1, the metal layer 142 is directly in contact with the bottom surface 134 of the lower core dielectric layer 114. The lower laminate stack 110 also includes interconnections (e.g., conductive vias 174) between the metal layers and through the dielectric layer(s). Although FIG. 1 illustrates the lower laminate stack 110 as including two metal layers and one dielectric layer therebetween, in some implementations, the set of lower metal layers can include more than two metal layers, and dielectric layers therebetween.

The lower laminate stack 110 also includes a set of contact pads (e.g., a contact pad 194 in the metal layer 144) configured to electrically connect the substrate 102 and/or components coupled thereto (e.g., the die 104) to off-package device(s) via the off-package contacts 166. For example, in FIG. 1, the contact pad 194 is electrically connected to a ball grid array contact 170 of the off-package contacts 166 that extends through a solder resist layer 192 of the lower laminate stack 110. The contact pad 194 is also connected to a pad or trace (e.g., a trace 180) of the metal layer 142 by one of the conductive vias 174. The metal layer 142 is patterned to form traces that are coupled to the metal layer 146 by way of conductive vias 164 through the core 106, and the metal layer 146 is patterned to form traces that are electrically connected to the contacts 178 of the passive electronic component 130, to the contacts 186 of the die 104, or both, through conductors of the upper laminate stack 108.

Because the closest metal layer (e.g., the metal layer 146) above the core 106 is on a surface (e.g., the top surface 132 of the upper core dielectric layer 112) that covers the passive electronic component 130, the closest metal layer above the core 106 can be patterned to form traces and/or pads in a region directly over the passive electronic component 130. For example, in FIG. 1, the trace 152 is in the closest metal layer to the core 106 and extends through a region corresponding to the shadow 172 of the passive electronic component 130. Thus, the upper laminate stack 108 provides more routing flexibility than would be available if the closest metal layer to the core 106 did not include traces and/or contacts in the region corresponding to the shadow 172 of the passive electronic component 130, as is the case for conventional embedded cores.

Similarly, in FIG. 1, the closest metal layer (e.g., the metal layer 142) beneath the core 106 is on a surface (e.g., the bottom surface 134 of the lower core dielectric layer 114) that covers the passive electronic component 130. As a result, the closest metal layer beneath the core 106 can be patterned to form traces and/or pads in a region directly below the passive electronic component 130. For example, in FIG. 1, the trace 180 is in the closest metal layer beneath the core 106 and extends through the shadow 172 of the passive electronic component 130. Thus, the lower laminate stack 110 provides more routing flexibility than would be available if the closest metal layer beneath the core 106 did not include traces and/or contacts in the shadow 172 of the passive electronic component 130, as is the case for conventional embedded cores.

FIG. 2 illustrates a schematic cross-sectional profile view of another example of a device 200 that includes the substrate 102 of FIG. 1. The device 200 of FIG. 2 includes the die 104 coupled to the substrate 102. The die 104 and the substrate 102 include the same features as described above with reference to FIG. 1, though certain features are not reproduced in FIG. 2 for clarity. Additionally, the device 200 includes one or more additional devices coupled to the substrate 102. For example, the device 200 includes a die 202 coupled to the substrate 102 via one or more interconnects 208 and a redistribution structure 206. The redistribution structure 206 can include a second substrate or a set of redistribution layers. In either case, the redistribution structure 206 includes a plurality of metal layers that are patterned and interconnected to form conductive paths through a set of dielectric layers. The substrate 102 can include one or more contacts 210 electrically connected to the one or more interconnects 208 to provide conductive paths between the die 104 and the die 202, between the die 202 and the passive electronic component 130, between the die 202 and the off-package contacts 166, or a combination thereof.

FIG. 3 illustrates a schematic cross-sectional profile view of another example of a device 300 that includes the substrate 102 of FIG. 1. The device 300 of FIG. 3 includes the die 104 coupled to the substrate 102. The die 104 and the substrate 102 include the same features as described above with reference to FIG. 1, though certain features are not reproduced in FIG. 2 for clarity. Additionally, the device 300 includes one or more additional devices coupled to the substrate 102. For example, the device 300 includes a die 302 coupled to contacts 304 of the substrate 102 side-by-side with the die 104. In this example, the conductors of the substrate 102 can define conductive paths between the die 104 and the die 302. Additionally, or alternatively, the conductors of the substrate 102 can define conductive paths between the die 302 and the passive electronic component 130, between the die 302 and the off-package contacts 166, or both.

Although FIGS. 1-3 illustrate individual dies coupled to the substrate 102, in some implementations, one or more of the dies include or correspond to chiplets which are interconnected through the substrate 102 or stacked and coupled as a stack to the substrate 102. In a stacked chiplet arrangement, one chiplet is stacked on top of and electrically connected to another chiplet. Using chiplets arranged and interconnected as a 3D stack can provide various benefits as compared to providing the same functional circuitry in one monolithic chip. For example, each chiplet is smaller than a monolithic die including all of the same functional circuit blocks would be. Since yield loss in IC manufacturing tends to increase as the die size increases, using smaller dies can reduce yield loss (i.e., increase yield) of the IC manufacturing process. Another benefit is that the chiplets can be fabricated in different locations and/or by different manufacturers, and in some cases, using different fabrication technologies (e.g., different fabrication technology nodes). As an example, one chiplet of an integrated device can include components (e.g., interconnects, transistors, etc.) that have a first minimum size, and another chiplet of the integrated device can include components (e.g., interconnects, transistors, etc.) that have a second minimum size, where the second minimum size is greater than the first minimum size. In contrast, all of the circuitry of a monolithic die is fabricated using the same fabrication technologies and equipment. As a result, when manufacturing a monolithic die, the entire die may be subject to the tightest manufacturing constraint of the most complex component of the monolithic die. In contrast, when using chiplets, different chiplets can be manufactured using different fabrication technologies (e.g., different fabrication technology nodes), and only the chiplet or chiplets that include the most complex components are subjected to the tightest manufacturing constraints. In this arrangement, chiplets fabricated using less expensive and/or higher yield fabrication technologies can be integrated with chiplets fabricated using more expensive and/or lower yield fabrication technologies to form an integrated device, resulting in overall savings. Still further, in some cases, as technology improves, the design of one or both of the chiplets can be changed such that new chiplet design is integrated with an older chiplet design, which improves manufacturing flexibility and reduces design costs.

In various implementations, any of the devices 100, 200, or 300 can include components such as a power management integrated circuit (PMIC), an application processor (including one or more processor cores), a modem, a radio frequency (RF) device, a passive device, a filter, a capacitor, an inductor, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory (including multiple memory cells), a power management processor, and/or combinations thereof. In such implementations, the dies 104, 202, 302 can operate as any of these components (or a combination of these components) that includes active circuitry.

### Exemplary Sequence for Fabricating a Device Including Substrate with Passive Electronic Component Embedded Therein

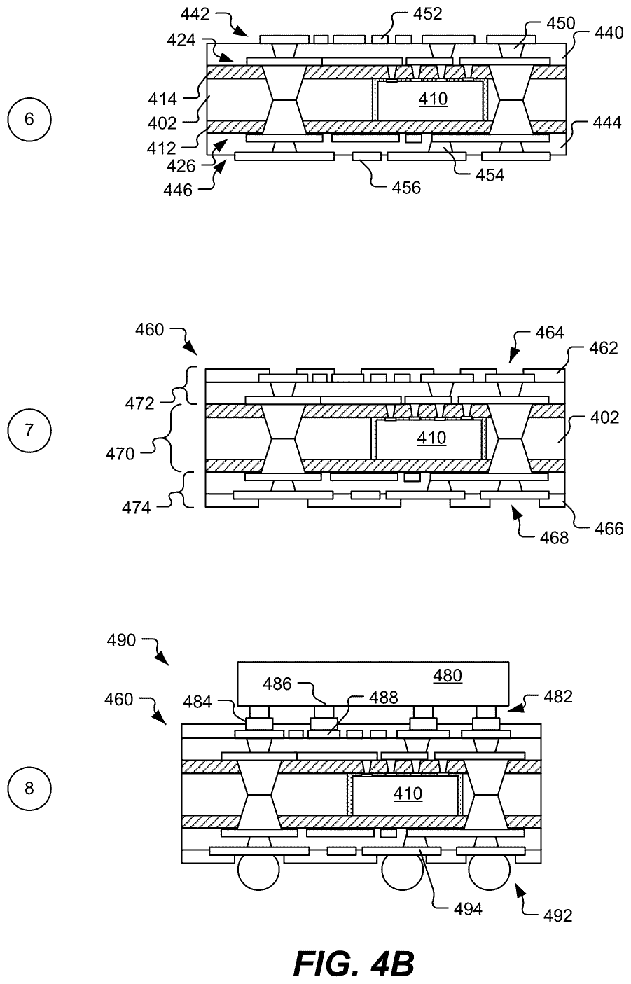

In some implementations, fabricating a device that includes a substrate including a passive electronic component embedded therein includes several processes. FIGS. 4A and 4B illustrate an exemplary sequence for providing or fabricating a device that includes a substrate including a passive electronic component embedded therein, as described with reference to any of FIGS. 1-3. In some implementations, the sequence of FIGS. 4A and 4B may be used to provide (e.g., during fabrication of) the device 100 of FIG. 1, the device 200 of FIG. 2, or the device 300 of FIG. 3.

It should be noted that the sequence of FIGS. 4A and 4B may combine one or more stages in order to simplify and/or clarify the sequence for providing or fabricating an integrated device. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIGS. 4A and 4B.

Stage 1 of FIG. 4A illustrates a state after formation of an opening 404 in a core 402. In the example illustrated in FIG. 4A, a supporting layer 406 is applied to the core 402 before or after formation of the opening 404. For example, the supporting layer 406 can correspond to or include a tape layer applied to one of the surfaces of the core 402. In a particular implementation, the core 402 corresponds to or includes the central core dielectric layer 116 of FIG. 1. The opening 404 can be formed, for example, using one or more cutting operations, such as laser cutting.

Stage 2 illustrates a state after placement of a passive electronic component 410 in the opening 404. The passive electronic component 410 can correspond to or include the passive electronic component 130 of FIG. 1. To illustrate, the passive electronic component 410 can include an integrated capacitor device. In the example illustrated in FIG. 4A, the passive electronic component 410 is shown as positioned “face down” (e.g., with contacts facing the supporting layer 406); however, in other implementations, the passive electronic component 410 can be positioned “face up” (e.g., with contacts facing away from the supporting layer 406). The supporting layer 406 supports and retains the passive electronic component 410 within the opening 404.

Stage 3 illustrates a state after formation or application of a first build-up layer 412 on the core 402 and application of a resin 411 within portions of the opening 404 not filled by the passive electronic component 410. The first build-up layer 412 corresponds to or includes the upper core dielectric layer 112 or the lower core dielectric layer 114, and the resin 411 corresponds to or includes the resin 196 of FIG. 1.

In some implementations, the first build-up layer 412 and the resin 411 are applied concurrently. In some examples, a resin can be applied to the core 402 such that the resin at least partially encapsulates the passive electronic component 410 and forms the resin 411 and the first build-up layer 412. In some such examples, the resin applied to concurrently form the first build-up layer 412 and the resin 411 includes a liquid or gel that is applied via a fluid application process (e.g., using one or more spraying, rolling, dipping, or spin-on operations). In other such examples, the resin is incorporated in a pre-preg material that includes the resin and a carrier medium, such as a fiber mat or tape material, which can be applied using composite layup operations.

Stage 4 illustrates a state after removal of the supporting layer 406; formation of a second build-up layer 414; formation of openings 416 through the first build-up layer 412, the core 402, and the second build-up layer 414; and formation of openings 418 through the second build-up layer 414. The second build-up layer 414 can be formed in a similar manner as described above with reference to formation of the first build-up layer 412 at Stage 3. The second build-up layer 414 corresponds to or includes the upper core dielectric layer 112 or the lower core dielectric layer 114 of FIG. 1. For example, if the first build-up layer 412 corresponds to the upper core dielectric layer 112, then the second build-up layer 414 corresponds to the lower core dielectric layer 114. Alternatively, if the first build-up layer 412 corresponds to the lower core dielectric layer 114, then the second build-up layer 414 corresponds to the upper core dielectric layer 112.

The openings 416 and 418 can be formed after curing of the build-up layers 412, 414. The openings 416, 418 can be formed using one or more material removal operations, such as etching, mechanical drilling, laser drilling, etc. The openings 416 are through openings extending from one side to the other of a workpiece 415, where the workpiece 415 corresponds to or includes the core 106 of FIG. 1. The openings 418 extend through the second build-up layer 414 to expose contacts of the passive electronic component 410.

Stage 5 illustrates a state after formation of conductive vias 420, 422 and formation and patterning of metal layers 424, 426. The conductive vias 420 are formed within the openings 416 and correspond to or include the conductive vias 164 of FIG. 1. The conductive vias 422 are formed within the openings 418 and correspond to or include the conductive vias 176 of FIG. 1. The metal layer 424 is formed on (e.g., directly in contact with a surface of) the first build-up layer 412 and corresponds to or includes the metal layer 142 of FIG. 1. The metal layer 426 is formed on (e.g., directly in contact with a surface of) the second build-up layer 414 and corresponds to or includes the metal layer 146 of FIG. 1. The metal layer 424 is patterned to include conductive features 432 (e.g., traces or pads), which may include traces or pads within a region directly over (in the orientation shown in FIG. 4A) the passive electronic component 410. For example, the conductive features 432 may include traces or pads that are in a shadow of the passive electronic component 410. Similarly, the metal layer 426 is patterned to include conductive features 430 (e.g., traces or pads), which may include traces or pads within a region directly under (in the orientation shown in FIG. 4A) the passive electronic component 410. For example, the conductive features 426 may include traces or pads that are in a shadow of the passive electronic component 410.

In some implementations, the metal layers 424, 426 are formed and patterned concurrently with formation of the conductive vias 420, 422. For example, patterned films can be applied to the first and second build-up layers 412, 414 to define openings for the features 432, 430 of the metal layer 424, 426 and the conductive vias 420, 422. In this example, the metal layers 424, 426 and the conductive vias 420, 422 can be formed using a plating or deposition process guided by the patterned film. In other implementations, the conductive vias 420, 422 and the metal layers 424, 426 are formed in separate operations.

Stage 6 of FIG. 4B (which is inverted relative to the orientation illustrated at Stage 5 of FIG. 4A) illustrates formation and interconnection of additional metal layers. In FIG. 4B, the formation and interconnection of the additional metal layers includes formation of a dielectric layer 440 over the metal layer 424, formation of a metal layer 442 on the dielectric layer 440, and formation of one or more conductive vias 450 electrically connecting the metal layer 424 and the metal layer 442. Further, in FIG. 4B, the formation and interconnection of the additional metal layers includes formation of a dielectric layer 444 over the metal layer 426, formation of a metal layer 446 on the dielectric layer 444, and formation of one or more conductive vias 454 electrically connecting the metal layer 426 and the metal layer 446. The metal layers 442, 446 are patterned to include conductive features 452, 456 (e.g., traces or pads). In some implementations, the metal layer 442 corresponds to or includes the metal layer 148 of FIG. 1, and the metal layer 446 corresponds to or includes the metal layer 144 of FIG. 1.

In some implementations, the metal layers 442, 446 are formed and patterned concurrently with formation of the conductive vias 450, 454, as described above with respect to Stage 5. In other implementations, the conductive vias 450, 454 and the metal layers 424, 426 are formed in separate operations. Although FIG. 4B illustrates only two metal layers on each side of the core 402, in other implementations, more than two metal layers can be formed on each side of the core 402 by repeating the operations described with reference to Stage 6.

Stage 7 illustrates a state after formation and patterning of a solder resist layer 462 over a top metal layer (e.g., the metal layer 442 shown in Stage 6) and formation and patterning of a solder resist layer 466 over a bottom metal layer (e.g., the metal layer 446 shown in Stage 6). The solder resist layer 462 is patterned to form openings 464 to expose contacts (e.g., one or more of the conductive features) of the top metal layer, and the solder resist layer 466 is patterned to form openings 468 to expose contacts (e.g., one or more of the conductive features) of the bottom metal layer. Formation of a substrate 460 that includes the passive electronic component 410 embedded therein is complete at Stage 7. The substrate 460 includes a core portion 470 that corresponds to or includes the core 106 of FIG. 1, includes an upper portion 472 that corresponds to or includes the upper laminate stack 108 of FIG. 1, and includes a lower portion 474 that corresponds to or includes the lower laminate stack 110 of FIG. 1.

Stage 8 illustrates a state after one or more dies (including a die 480) are attached to the substrate 460 to form a device 490. For example, contacts 486 of the die 480 can be electrically connected, via solder bumps 482 and bump pads 484, to corresponding contacts 488 of the substrate 460. The device 490 can include solder balls 492 electrically connected to corresponding contacts 494 of the substrate 460 to enable connection of the device 490 to other devices. To illustrate, the solder bumps 482 of the die 480 can be positioned on the bump pads 484 and heated to reflow the solder bumps 482 to form physical and electrical connections between the contacts 486 and the contacts 488.

### Exemplary Flow Diagrams of Methods for Fabricating a Device Including Substrate with Passive Electronic Component Embedded Therein

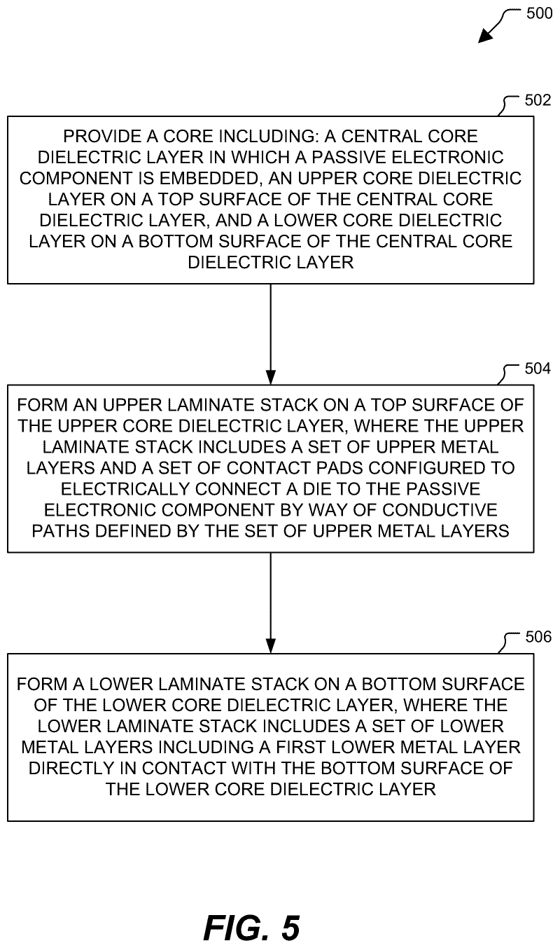

In some implementations, fabricating a device that includes a substrate including a passive electronic component embedded therein includes several processes. FIG. 5 illustrates an exemplary flow diagram of a method 500 for providing or fabricating a device that includes a substrate including a passive electronic component embedded therein. In some implementations, the method 500 of FIG. 5 may be used to provide or fabricate any of the device 100 of FIG. 1, the device 200 of FIG. 2, the device 300 of FIG. 3, or the device 490 of FIG. 4B. It should be noted that the method 500 of FIG. 5 may combine one or more processes in order to simplify and/or clarify the method for providing or fabricating an integrated device. In some implementations, the order of the processes may be changed or modified.

The method 500 includes, at block 502, providing a core including a central core dielectric layer in which a passive electronic component is embedded, an upper core dielectric layer on a top surface of the central core dielectric layer, and a lower core dielectric layer on a bottom surface of the central core dielectric layer. For example, the core can include or correspond to the core 106 of FIG. 1, which includes the upper core dielectric layer 112, the lower core dielectric layer 114, and the central core dielectric layer 116 in which the passive electronic component 130 is embedded. As another example, the core can correspond to or include the core portion 470 of FIG. 4B, which includes the first build-up layer 412, the second build-up layer 414, and the core 402 in which the passive electronic component 410 is embedded. Stages 1-5 of FIG. 4A illustrate examples of operations that can be used to provide (e.g., to fabricate) the core.

The method 500 includes, at block 504, forming an upper laminate stack on a top surface of the upper core dielectric layer. The upper laminate stack includes a set of upper metal layers and a set of contact pads configured to electrically connect a die to the passive electronic component by way of conductive paths defined by the set of upper metal layers. For example, the upper laminate stack can include or correspond to the upper laminate stack 108 of FIG. 1. In this example, the upper laminate stack 108 includes the metal layers 146, 148 and the dielectric layer 150 therebetween. The metal layers 146, 148 define traces and pads that are interconnected by vias 182 to form conductive paths between contacts 178 of the passive electronic component 130 and contact pads 138, which are electrically connected, in FIG. 1, to contacts 186 of the die 104. As another example, the upper laminate stack can correspond to or include the upper portion 472 of FIG. 4B. In this example, the upper portion 472 includes the metal layers 424, 442 and the dielectric layer 440 therebetween. The metal layers 424, 442 define conductive features 432, 452 that are interconnected by vias 450 to form conductive paths between contacts of the passive electronic component 130 and contacts 488, which are configured to be electrically connected to contacts 486 of the die 480. Stages 5-7 of FIGS. 4A and 4B illustrate examples of operations that can be used to form an upper laminate stack on the top surface of the upper core dielectric layer.

The method 500 includes, at block 506, forming a lower laminate stack on a bottom surface of the lower core dielectric layer. The lower laminate stack includes a set of lower metal layers including a first lower metal layer directly in contact with the bottom surface of the lower core dielectric layer. For example, the lower laminate stack can include or correspond to the lower laminate stack 110 of FIG. 1. In this example, the lower laminate stack 110 includes the metal layers 142, 144 and the dielectric layer 140 therebetween. In this example, the metal layer 142 is directly in contact with the bottom surface 134 of the lower core dielectric layer 114. As another example, the lower laminate stack can correspond to or include the lower portion 474 of FIG. 4B. In this example, the lower portion 474 includes the metal layers 426, 446 and the dielectric layer 444 therebetween. In this example, the metal layer 426 is directly in contact with a bottom surface of the second build-up layer 414. Stages 5-7 of FIGS. 4A and 4B illustrate examples of operations that can be used to form a lower laminate stack on the bottom surface of the lower core dielectric layer (e.g., on the second build-up layer 414).

In some implementations, before forming the upper laminate stack, the method 500 includes forming first openings that extend through the upper core dielectric layer, the central core dielectric layer, and the lower core dielectric layer; forming second openings that extend through the upper core dielectric layer to expose contacts of the passive electronic component; and forming first conductive vias within the first openings and second conductive vias within the second openings, wherein one or more first traces of the set of upper metal layers are electrically connected to the first conductive vias and one or more second traces of the set of upper metal layers are electrically connected to the second conductive vias. For example, as described with reference to Stages 4 and 5 of FIG. 4A, openings 416 can be formed to extend through the first build-up layer 412. the second build-up layer 414, and the core 402, and openings 418 can be formed to extend through the second build-up layer 414. In this example, the first build-up layer 412 corresponds to the lower core dielectric layer, the second build-up layer 414 corresponds to the upper core dielectric layer, and the core 402 corresponds to the central core dielectric layer.

In a particular implementation, the method 500 includes electrically connecting a PDN of a die to a set of contact pads to provide a conductive path between the PDN and the passive electronic component. For example, the PDN 162 of the die 104 is electrically connected, through conductors of the upper laminate stack 108 and the vias 176, to the contacts 178 of the passive electronic component 130.

In some implementations, the method 500 further includes forming a set of BGA contacts on a bottom surface of the lower laminate stack and electrically connected to the set of lower metal layers. In some such implementations, at least one BGA contact of the set of BGA contacts is disposed at least partially within a shadow of the passive electronic component. For example, the device 100 of FIG. 1 includes the off-package contacts 166, which include solder balls arranged in a ball grid array and electrically connected to the metal layers 144, 142 of the lower laminate stack 110. In this example, the BGA contact 170 is disposed at least partially within the shadow 172 of the passive electronic component 130.

In some implementations, providing the core includes forming an opening in a central core dielectric layer, positioning a passive electronic component within the opening and supported by a supporting layer, applying resin to at least partially encapsulate the passive electronic component within the opening and resin to form a first build-up layer on the central core dielectric layer, and coupling a second build-up layer to the central core dielectric layer. In such implementations, the first build-up layer corresponds to the lower core dielectric layer or the upper core dielectric layer, and the second build-up layer corresponds to the other of the lower core dielectric layer or the upper core dielectric layer. In some such implementations, providing the core also includes removing the supporting layer after applying the resin to at least partially encapsulate the passive electronic component and before coupling the second build-up layer to the central core dielectric layer. In some such implementations, coupling the second build-up layer to the central core dielectric layer includes applying a resin to the top surface of the central core dielectric layer and curing the resin to form the second build-up layer. Examples of operations that can be used to provide the core in such implementations are described with reference to Stages 1-4 of FIG. 4A.

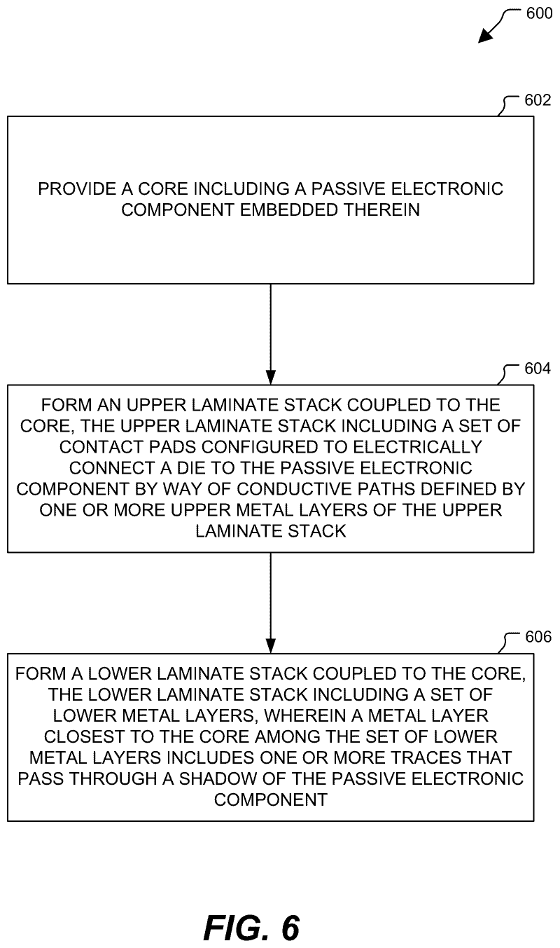

FIG. 6 illustrates an exemplary flow diagram of another method 600 for providing or fabricating a device that includes a substrate including a passive electronic component embedded therein. In some implementations, the method 600 of FIG. 6 may be used to provide or fabricate any of the device 100 of FIG. 1, the device 200 of FIG. 2. the device 300 of FIG. 3, or the device 490 of FIG. 4B. It should be noted that the method 600 of FIG. 6 may combine one or more processes in order to simplify and/or clarify the method for providing or fabricating an integrated device. In some implementations, the order of the processes may be changed or modified.

The method 600 includes, at block 602, providing a core including a passive electronic component embedded therein. For example, the core can include or correspond to the core 106 of FIG. 1 in which the passive electronic component 130 is embedded. As another example, the core can correspond to or include the core portion 470 of FIG. 4B in which the passive electronic component 410 is embedded. Stages 1-4 of FIG. 4A illustrate examples of operations that can be used to provide (e.g., to fabricate) the core.

The method 600 includes, at block 604, forming an upper laminate stack coupled to the core. The upper laminate stack includes a set of contact pads configured to electrically connect a die to the passive electronic component by way of conductive paths defined by one or more upper metal layers of the upper laminate stack. For example, the upper laminate stack can include or correspond to the upper laminate stack 108 of FIG. 1. In this example, the upper laminate stack 108 includes the metal layers 146, 148 and the dielectric layer 150 therebetween. The metal layers 146, 148 define traces and pads that are interconnected by vias 182 to form conductive paths between contacts 178 of the passive electronic component 130 and contact pads 138, which are electrically connected, in FIG. 1, to contacts 186 of the die 104. As another example, the upper laminate stack can correspond to or include the upper portion 472 of FIG. 4B. In this example, the upper portion 472 includes the metal layers 424, 442 and the dielectric layer 440 therebetween. The metal layers 424, 442 define conductive features 432, 452 that are interconnected by vias 450 to form conductive paths between contacts of the passive electronic component 130 and contacts 488, which are configured to be electrically connected to contacts 486 of the die 480. Stages 5-7 of FIGS. 4A and 4B illustrate examples of operations that can be used to form an upper laminate stack on the top surface of the upper core dielectric layer (e.g., on the second build-up layer 414).

The method 600 includes, at block 606, forming a lower laminate stack coupled to the core. The lower laminate stack includes a set of lower metal layers, and a metal layer closest to the core among the set of lower metal layers includes one or more traces that pass through a shadow of the passive electronic component. For example, the lower laminate stack can include or correspond to the lower laminate stack 110 of FIG. 1. In this example, the lower laminate stack 110 includes the metal layers 142, 144 and the dielectric layer 140 therebetween. In this example, the metal layer 142 is closest to the core 106 among the metal layers 142, 144 of the lower laminate stack 110, and the metal layer 142 includes the trace 180 that extends into the shadow 172 of the passive electronic component 130. Stages 5-7 of FIGS. 4A and 4B illustrate examples of operations that can be used to form a lower laminate stack on the bottom surface of the lower core dielectric layer (e.g., on the first build-up layer 412).

In some implementations, before forming the upper laminate stack, the method 600 includes forming first openings that extend through the upper core dielectric layer, the central core dielectric layer, and the lower core dielectric layer; forming second openings that extend through the upper core dielectric layer to expose contacts of the passive electronic component; and forming first conductive vias within the first openings and second conductive vias within the second openings, wherein one or more first traces of the set of upper metal layers are electrically connected to the first conductive vias and one or more second traces of the set of upper metal layers are electrically connected to the second conductive vias. For example, as described with reference to Stages 4 and 5 of FIG. 4A, openings 416 can be formed to extend through the first build-up layer 412, the second build-up layer 414 and the core 402, and openings 418 can be formed to extend through the second build-up layer 414. In this example, the first build-up layer 412 corresponds to the lower core dielectric layer, the second build-up layer 414 corresponds to the upper core dielectric layer, and the core 402 corresponds to the central core dielectric layer.

In a particular implementation, the method 600 includes electrically connecting a PDN of a die to a set of contact pads to provide a conductive path between the PDN and the passive electronic component. For example, the PDN 162 of the die 104 is electrically connected, through conductors of the upper laminate stack 108 and the vias 176, to the contacts 178 of the passive electronic component 130.

In some implementations, the method 600 further includes forming a set of BGA contacts on a bottom surface of the lower laminate stack and electrically connected to the set of lower metal layers. In some such implementations, at least one BGA contact of the set of BGA contacts is disposed at least partially within a shadow of the passive electronic component. For example, the device 100 of FIG. 1 includes the off-package contacts 166, which include solder balls arranged in a ball grid array and electrically connected to the metal layers 144, 142 of the lower laminate stack 110. In this example, the BGA contact 170 is disposed at least partially within the shadow 172 of the passive electronic component 130.

In some implementations, providing the core includes forming an opening in a central core dielectric layer, positioning a passive electronic component within the opening and supported by a supporting layer, applying resin to at least partially encapsulate the passive electronic component within the opening and resin to form a first build-up layer on the central core dielectric layer, and coupling a second build-up layer to the central core dielectric layer. In such implementations, the first build-up layer corresponds to the lower core dielectric layer or the upper core dielectric layer, and the second build-up layer corresponds to the other of the lower core dielectric layer or the upper core dielectric layer. In some such implementations, providing the core also includes removing the supporting layer after applying the resin to at least partially encapsulate the passive electronic component and before coupling the second build-up layer to the central core dielectric layer. In some such implementations, coupling the second build-up layer to the central core dielectric layer includes applying a resin to the top surface of the central core dielectric layer and curing the resin to form the second build-up layer. Examples of operations that can be used to provide the core in such implementations are described with reference to Stages 1-4 of FIG. 4A.

### Exemplary Electronic Devices

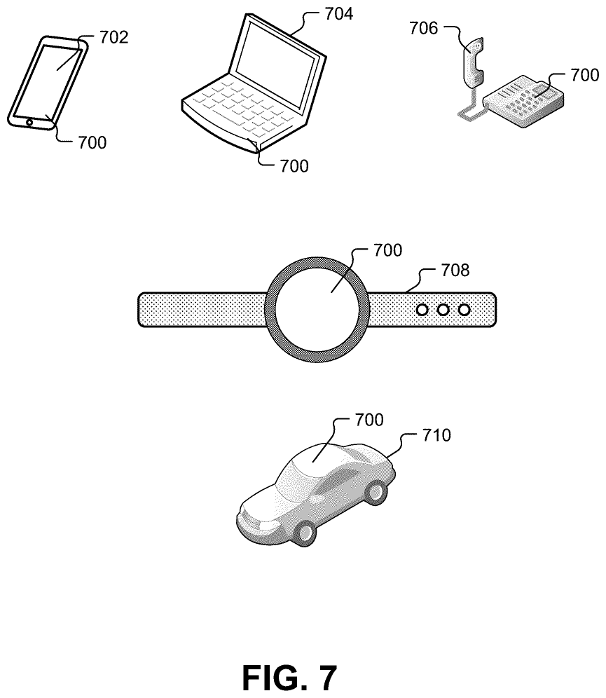

FIG. 7 illustrates various electronic devices that may include or be integrated with the device 100 of FIG. 1, the device 200 of FIG. 2, the device 300 of FIG. 3, the substrate 460 of FIG. 4B, or the device 490 of FIG. 4B. For example, a mobile phone device 702, a laptop computer device 704, a fixed location terminal device 706, a wearable device 708, or a vehicle 710 (e.g., an automobile or an aerial device) may include a device 700. The device 700 can include, for example, the device 100 of FIG. 1, the device 200 of FIG. 2, the device 300 of FIG. 3, the substrate 460 of FIG. 4B, the device 490 of FIG. 4B, or other devices described herein. The devices 702, 704, 706, and 708 and the vehicle 710 illustrated in FIG. 7 are merely exemplary. Other electronic devices may also feature the device 700 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1-7 may be rearranged and/or combined into a single component, process, feature or function or embodied in several components, processes, or functions. Additional elements, components, processes, and/or functions may also be added without departing from the disclosure. It should also be noted that FIGS. 1-7 and their corresponding descriptions in the present disclosure are not limited to dies and/or ICs. In some implementations, FIGS. 1-7 and their corresponding descriptions may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures are schematic and may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C. then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to as a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, refers a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, a device includes a core, which includes an upper core dielectric layer; a lower core dielectric layer; a central core dielectric layer in direct contact with a bottom surface of the upper core dielectric layer and in direct contact with a top surface of the lower core dielectric layer; and a passive electronic component embedded within the central core dielectric layer. The device also includes an upper laminate stack coupled to a top surface of the upper core dielectric layer. The upper laminate stack includes: a set of upper metal layers; and a set of contact pads configured to electrically connect a die to the passive electronic component by way of conductive paths defined by the set of upper metal layers. The device also includes a lower laminate stack coupled to a bottom surface of the lower core dielectric layer. The lower laminate stack includes a set of lower metal layers including a first lower metal layer directly in contact with the bottom surface of the lower core dielectric layer; and a set of lower dielectric layers disposed between adjacent metal layers of the set of lower metal layers.

Example 2 includes the device of Example 1, wherein the upper laminate stack further comprises a set of upper dielectric layers disposed between adjacent metal layers of the set of upper metal layers.

Example 3 includes the device of Example 1 or Example 2, wherein the set of upper metal layers includes a first upper metal layer directly in contact with the top surface of the upper core dielectric layer.

Example 4 includes the device of any of Examples 1 to 3, wherein the set of lower metal layers includes a first lower metal layer directly in contact with the bottom surface of the lower core dielectric layer.

Example 5 includes the device of any of Examples 1 to 4, wherein a metal layer closest to the core among the set of lower metal layers includes one or more traces that pass through a shadow of the passive electronic component.

Example 6 includes the device of any of Examples 1 to 5, wherein the passive electronic component includes an integrated capacitor device.

Example 7 includes the device of any of Examples 1 to 6 and further includes the die, wherein a power distribution network of the die is coupled to the passive electronic component via the set of contact pads and the conductive paths defined by the set of upper metal layers.

Example 8 includes the device of Example 7, wherein the die comprises a plurality of transistors.

Example 9 includes the device of Example 7 or Example 8 and further includes one or more additional components electrically connected to the die via the conductive paths defined by the set of upper metal layers.

Example 10 includes the device of any of Examples 1 to 9 and further includes a plurality of conductive vias extending through the core and electrically interconnecting the set of upper metal layers and the set of lower metal layers.

Example 11 includes the device of any of Examples 1 to 10 and further includes a set of BGA contacts on a bottom surface of the lower laminate stack and configured to electrically connect the device to another device or substrate.

Example 12 includes the device of Example 11, wherein at least one BGA contact of the set of BGA contacts is positioned at least partially within a shadow of the passive electronic component.

According to Example 13, a device includes a core including a passive electronic component embedded therein. The device also includes an upper laminate stack coupled to the core and comprising a set of contact pads configured to electrically connect a die to the passive electronic component by way of conductive paths defined by one or more upper metal layers of the upper laminate stack. The device further includes a lower laminate stack coupled to the core and comprising a set of lower metal layers. A metal layer closest to the core among the set of lower metal layers includes one or more traces that pass through a shadow of the passive electronic component.

Example 14 includes the device of Example 13, wherein the upper laminate stack further comprises a set of upper dielectric layers disposed between adjacent metal layers of the set of upper metal layers.

Example 15 includes the device of Example 13 or Example 14, wherein the set of upper metal layers includes a first upper metal layer directly in contact with a top surface of an upper core dielectric layer of the core.

Example 16 includes the device of any of Examples 13 to 15, wherein the metal layer closest to the core among the set of lower metal layers contacts a bottom surface of a lower core dielectric layer of the core.

Example 17 includes the device of any of Examples 13 to 16, wherein the passive electronic component includes a capacitor device.

Example 18 includes the device of any of Examples 13 to 17 and further includes the die, wherein a power distribution network of the die is coupled, via the set of contact pads and the conductive paths defined by the set of upper metal layers to the passive electronic component.

Example 19 includes the device of any of Examples 13 to 18, wherein the die comprises a plurality of transistors.

Example 20 includes the device of any of Examples 13 to 19 and further includes one or more additional components electrically connected to the die via the conductive paths defined by the set of upper metal layers.

Example 21 includes the device of any of Examples 13 to 20 and further includes a plurality of conductive vias extending through the core to interconnect the set of upper metal layers and the set of lower metal layers.

Example 22 includes the device of any of Examples 13 to 21 and further includes a set of BGA contacts on a bottom surface of the lower laminate stack and configured to electrically connect the device to another device or substrate.

Example 23 includes the device of Example 22, wherein at least one BGA contact of the set of BGA contacts is positioned at least partially within the shadow of the passive electronic component.

According to Example 24, a method includes providing a core including a central core dielectric layer in which a passive electronic component is embedded, an upper core dielectric layer on a top surface of the central core dielectric layer, and a lower core dielectric layer on a bottom surface of the central core dielectric layer. The method also includes forming an upper laminate stack on a top surface of the upper core dielectric layer, the upper laminate stack including a set of upper metal layers and a set of contact pads configured to electrically connect a die to the passive electronic component by way of conductive paths defined by the set of upper metal layers. The method also includes forming a lower laminate stack on a bottom surface of the lower core dielectric layer, the lower laminate stack including a set of lower metal layers including a first lower metal layer directly in contact with the bottom surface of the lower core dielectric layer.

Example 25 includes the method of Example 24 and further includes, before forming the upper laminate stack: forming first openings that extend through the upper core dielectric layer, the central core dielectric layer, and the lower core dielectric layer; forming second openings that extend through the upper core dielectric layer to expose contacts of the passive electronic component; and forming first conductive vias within the first openings and second conductive vias within the second openings, wherein one or more first traces of the set of upper metal layers are electrically connected to the first conductive vias and one or more second traces of the set of upper metal layers are electrically connected to the second conductive vias.

Example 26 includes the method of Example 24 or Example 25, wherein one or more first traces of the set of lower metal layers are electrically connected to the first conductive vias.

Example 27 includes the method of Example 26, wherein the one or more first traces of the set of lower metal layers include at least one trace that passes through a shadow of the passive electronic component.

Example 28 includes the method of any of Examples 24 to 27 and further includes electrically connecting a PDN of the die to the set of contact pads to provide a conductive path between the PDN and the passive electronic component.

Example 29 includes the method of any of Examples 24 to 28 and further includes forming a set of BGA contacts on a bottom surface of the lower laminate stack and electrically connected to the set of lower metal layers, wherein at least one BGA contact of the set of BGA contacts is disposed at least partially within a shadow of the passive electronic component.

Example 30 includes the method of any of Examples 24 to 29, wherein providing the core comprises: forming an opening in the central core dielectric layer; positioning the passive electronic component within the opening and supported by a supporting layer; applying resin to at least partially encapsulate the passive electronic component within the opening and resin to form a first build-up layer on the central core dielectric layer; and coupling a second build-up layer to the central core dielectric layer, wherein the first build-up layer corresponds to the lower core dielectric layer or the upper core dielectric layer and the second build-up layer corresponds to the other of the lower core dielectric layer or the upper core dielectric layer.

Example 31 includes the method of Example 30, wherein providing the core further comprises removing the supporting layer after applying the resin to at least partially encapsulate the passive electronic component and before coupling the second build-up layer to the central core dielectric layer.

Example 32 includes the method of Example 30 or Example 31, wherein the resin that at least partially encapsulates the passive electronic component and the resin that forms the first build-up layer are applied concurrently.

Example 33 includes the method of any of Examples 30 to 32, wherein coupling the second build-up layer to the central core dielectric layer comprises applying a resin to a surface of the central core dielectric layer and curing the resin to form the second build-up layer.

According to Example 34, a method includes providing a core including a passive electronic component embedded therein; forming an upper laminate stack coupled to the core, the upper laminate stack including a set of contact pads configured to electrically connect a die to the passive electronic component by way of conductive paths defined by one or more upper metal layers of the upper laminate stack; and forming a lower laminate stack coupled to the core, the lower laminate stack including a set of lower metal layers, wherein a metal layer closest to the core among the set of lower metal layers includes one or more traces that pass through a shadow of the passive electronic component.

Example 35 includes the method of Example 34 and further includes electrically connecting a PDN of the die to the set of contact pads to provide a conductive path between the PDN and the passive electronic component.

Example 36 includes the method of Example 34 or Example 35 and further includes forming a set of BGA contacts on a bottom surface of the lower laminate stack and electrically connected to the set of lower metal layers, wherein at least one BGA contact of the set of BGA contacts is disposed at least partially within the shadow of the passive electronic component.

Example 37 includes the method of any of Examples 34 to 36, wherein providing the core comprises: forming an opening in a central core dielectric layer; positioning the passive electronic component within the opening and supported by a supporting layer; applying resin to at least partially encapsulate the passive electronic component within the opening and resin to form a first build-up layer on the central core dielectric layer; and coupling a second build-up layer to the central core dielectric layer, wherein the first build-up layer corresponds to a lower core dielectric layer or an upper core dielectric layer and the second build-up layer corresponds to the other of the lower core dielectric layer or the upper core dielectric layer.

Example 38 includes the method of Example 37, wherein providing the core further comprises removing the supporting layer after applying the resin to at least partially encapsulate the passive electronic component and before coupling the second build-up layer to the central core dielectric layer.

Example 39 includes the method of any of Examples 37 to 38, wherein the resin that at least partially encapsulates the passive electronic component and the resin that forms the first build-up layer are applied concurrently.

Example 40 includes the method of any of Examples 37 to 39, wherein coupling the second build-up layer to the central core dielectric layer comprises applying a resin to a surface of the central core dielectric layer and curing the resin to form the second build-up layer.

Example 41 includes the method of any of Examples 37 to 40 and further includes, before forming the upper laminate stack: forming first openings that extend through the upper core dielectric layer, the central core dielectric layer, and the lower core dielectric layer; forming second openings through the upper core dielectric layer to expose contacts of the passive electronic component; and forming first conductive vias within the first openings and second conductive vias within the second openings, wherein one or more first traces of the set of upper metal layers are electrically connected to the first conductive vias and one or more second traces of the set of upper metal layers are electrically connected to the second conductive vias.

Example 42 includes the method of Example 41, wherein the one or more traces that pass through the shadow of the passive electronic component are electrically connected to the first conductive vias.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A device comprising:
a core comprising:
an upper core dielectric layer;
a lower core dielectric layer;
a central core dielectric layer in direct contact with a bottom surface of the upper core dielectric layer and in direct contact with a top surface of the lower core dielectric layer; and
a passive electronic component embedded within the central core dielectric layer;
an upper laminate stack coupled to a top surface of the upper core dielectric layer and comprising:
a set of upper metal layers; and
a set of contact pads configured to electrically connect a die to the passive electronic component by way of conductive paths defined by the set of upper metal layers; and
a lower laminate stack coupled to a bottom surface of the lower core dielectric layer and comprising:
a set of lower metal layers including a first lower metal layer directly in contact with the bottom surface of the lower core dielectric layer; and
a set of lower dielectric layers disposed between adjacent metal layers of the set of lower metal layers.

2. The device of claim 1, wherein the upper laminate stack further comprises a set of upper dielectric layers disposed between adjacent metal layers of the set of upper metal layers.

3. The device of claim 1, wherein the set of upper metal layers includes a first upper metal layer directly in contact with the top surface of the upper core dielectric layer.

4. The device of claim 1, wherein the set of lower metal layers includes a first lower metal layer directly in contact with the bottom surface of the lower core dielectric layer.

5. The device of claim 1, wherein a metal layer closest to the core among the set of lower metal layers includes one or more traces that pass through a shadow of the passive electronic component.

6. The device of claim 1, wherein the passive electronic component includes an integrated capacitor device.

7. The device of claim 1, further comprising the die, wherein a power distribution network of the die is coupled to the passive electronic component via the set of contact pads and the conductive paths defined by the set of upper metal layers.

8. The device of claim 7, further comprising one or more additional components electrically connected to the die via the conductive paths defined by the set of upper metal layers.

9. The device of claim 1, further comprising a plurality of conductive vias extending through the core and electrically interconnecting the set of upper metal layers and the set of lower metal layers.

10. The device of claim 1, further comprising a set of ball grid array (BGA) contacts on a bottom surface of the lower laminate stack and configured to electrically connect the device to another device or substrate, wherein at least one BGA contact of the set of BGA contacts is positioned at least partially within a shadow of the passive electronic component.

11. A device comprising:
a core including a passive electronic component embedded therein;
an upper laminate stack coupled to the core and comprising a set of contact pads configured to electrically connect a die to the passive electronic component by way of conductive paths defined by one or more upper metal layers of the upper laminate stack; and
a lower laminate stack coupled to the core and comprising a set of lower metal layers, wherein a metal layer closest to the core among the set of lower metal layers includes one or more traces that pass through a shadow of the passive electronic component.

12. The device of claim 11, wherein the upper laminate stack further comprises a set of upper dielectric layers disposed between adjacent metal layers of the set of upper metal layers.

13. The device of claim 11, wherein the set of upper metal layers includes a first upper metal layer directly in contact with a top surface of an upper core dielectric layer of the core.

14. The device of claim 11, wherein the metal layer closest to the core among the set of lower metal layers contacts a bottom surface of a lower core dielectric layer of the core.

15. The device of claim 11, wherein the passive electronic component includes a capacitor device.

16. The device of claim 11, further comprising the die, wherein a power distribution network of the die is coupled, via the set of contact pads and the conductive paths defined by the set of upper metal layers to the passive electronic component.

17. The device of claim 11, further comprising one or more additional components electrically connected to the die via the conductive paths defined by the set of upper metal layers.

18. The device of claim 11, further comprising a plurality of conductive vias extending through the core to interconnect the set of upper metal layers and the set of lower metal layers.

19. The device of claim 11, further comprising a set of ball grid array (BGA) contacts on a bottom surface of the lower laminate stack and configured to electrically connect the device to another device or substrate, wherein at least one BGA contact of the set of BGA contacts is positioned at least partially within the shadow of the passive electronic component.

20. A method comprising:
providing a core including a central core dielectric layer in which a passive electronic component is embedded, an upper core dielectric layer on a top surface of the central core dielectric layer, and a lower core dielectric layer on a bottom surface of the central core dielectric layer;
forming an upper laminate stack on a top surface of the upper core dielectric layer, the upper laminate stack including a set of upper metal layers and a set of contact pads configured to electrically connect a die to the passive electronic component by way of conductive paths defined by the set of upper metal layers; and
forming a lower laminate stack on a bottom surface of the lower core dielectric layer, the lower laminate stack including a set of lower metal layers including a first lower metal layer directly in contact with the bottom surface of the lower core dielectric layer.

21. The method of claim 20, further comprising, before forming the upper laminate stack:
forming first openings that extend through the upper core dielectric layer, the central core dielectric layer, and the lower core dielectric layer;
forming second openings that extend through the upper core dielectric layer to expose contacts of the passive electronic component; and
forming first conductive vias within the first openings and second conductive vias within the second openings, wherein one or more first traces of the set of upper metal layers are electrically connected to the first conductive vias and one or more second traces of the set of upper metal layers are electrically connected to the second conductive vias.

22. The method of claim 21, wherein one or more first traces of the set of lower metal layers are electrically connected to the first conductive vias.

23. The method of claim 22, wherein the one or more first traces of the set of lower metal layers include at least one trace that passes through a shadow of the passive electronic component.

24. The method of claim 20, further comprising electrically connecting a power distribution network (PDN) of the die to the set of contact pads to provide a conductive path between the PDN and the passive electronic component.

25. The method of claim 20, further comprising forming a set of ball grid array (BGA) contacts on a bottom surface of the lower laminate stack and electrically connected to the set of lower metal layers, wherein at least one BGA contact of the set of BGA contacts is disposed at least partially within a shadow of the passive electronic component.

26. The method of claim 20, wherein providing the core comprises:
forming an opening in the central core dielectric layer;
positioning the passive electronic component within the opening and supported by a supporting layer;
applying resin to at least partially encapsulate the passive electronic component within the opening and resin to form a first build-up layer on the central core dielectric layer; and
coupling a second build-up layer to the central core dielectric layer, wherein the first build-up layer corresponds to the lower core dielectric layer or the upper core dielectric layer and the second build-up layer corresponds to the other of the lower core dielectric layer or the upper core dielectric layer.

27. The method of claim 26, wherein providing the core further comprises removing the supporting layer after applying the resin to at least partially encapsulate the passive electronic component and before coupling the second build-up layer to the central core dielectric layer.

28. The method of claim 26, wherein the resin that at least partially encapsulates the passive electronic component and the resin that forms the first build-up layer are applied concurrently.

29. The method of claim 26, wherein coupling the second build-up layer to the central core dielectric layer comprises:
applying a resin to a surface of the central core dielectric layer; and
curing the resin to form the second build-up layer.

30. A method comprising:
providing a core including a passive electronic component embedded therein;
forming an upper laminate stack coupled to the core, the upper laminate stack including a set of contact pads configured to electrically connect a die to the passive electronic component by way of conductive paths defined by one or more upper metal layers of the upper laminate stack; and
forming a lower laminate stack coupled to the core, the lower laminate stack including a set of lower metal layers, wherein a metal layer closest to the core among the set of lower metal layers includes one or more traces that pass through a shadow of the passive electronic component.
